(19) United States
(12) Patent Application Publication
(10) Pub. No.: US 2008/0242084 A1
(43) Pub. Date: Oct. 2, 2008

(54) METHOD FOR PLANARIZING AN INSULATION LAYER IN A SEMICONDUCTOR DEVICE CAPABLE OF OMITTING A MASK PROCESS AND AN ETCHING PROCESS

(76) Inventors: Hyung Hwan KIM, Gyeonggi-do (KR); Jong Goo JUNG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/939,631

(22) Filed: Nov. 14, 2007

(30) Foreign Application Priority Data
Mar. 30, 2007 (KR) 10-2007-0031926

(51) Int. Cl. H01L 21/4763

(52) U.S. Cl. 438/669; 257/E21.496

(57) ABSTRACT

In a method for planarizing an insulation layer in a semiconductor device, an insulation layer is formed over a semiconductor substrate having a cell region and a peripheral region. The cell region is higher than the peripheral region due to a capacitor formed in the cell region. A metal layer is formed over the insulation layer. The metal layer is chemical mechanical polished to expose the insulation layer portion in the cell region. The exposed insulation layer portion in the cell region is chemical mechanical polishing to planarize the insulation layer, and the planarized insulation layer and the remaining metal layer are chemical mechanical polishing to remove the metal layer remained in the peripheral region. The method for planarizing an insulation layer does not require a separate photosensitive layer forming process or a dry etching process.

### CROSS-REFERENCE TO RELATED APPLICATIONS

The present application claims priority to Korean patent application number 10-2007-0031926 filed on Mar. 30, 2007, which is incorporated herein by reference in its entirety.

### BACKGROUND OF THE INVENTION

The present invention relates to a method for manufacturing a semiconductor device, and more particularly, to a method for planarizing an insulation layer formed in a structure which causes a height difference between the insulation layer in a cell region and the insulation layer in a peripheral region of a semiconductor device.

A sharp increase in the demand for semiconductor devices has led to the suggestion of various technologies for achieving a high capacity capacitor. The capacitor's structure includes a dielectric film interposed between a storage electrode and a plate electrode. The capacitor's capacity is proportional to the surface area of the electrode and a dielectric constant and is inversely proportional to a space between the electrodes, i.e. a thickness of the dielectric film. Therefore, in order to produce a high capacity capacitor, it is necessary to use a dielectric film having a high dielectric constant, increase a surface area of a storage electrode, or shorten a distance between electrodes.

Currently, a capacitor having a cylindrical structure that ensures a large electrode area with a relatively simple process is largely used as the storage electrode of a capacitor.

An interlayer insulation layer is formed for insulating a plate electrode and a subsequently formed metal wiring. A height difference between the interlayer insulation in the region formed with the capacitor, (i.e. a cell region) and the interlayer insulation in the region formed with no capacitor (i.e. a peripheral region) is caused by the capacitor, which has a large height. To remove this height differential, a planarization of the interlayer insulation layer is implemented for eliminating the height difference caused by the capacitor.

FIGS. 1A to 1C are cross-sectional views illustrating steps of a prior art method for planarizing an insulation layer to eliminate the height difference of the insulation layer caused by a cylindrical capacitor.

Referring to FIG. 1A, a storage electrode 140 having a cylindrical structure is formed over a cell region of the semiconductor substrate 110. The semiconductor substrate 110 is defined by the cell region and a peripheral region and is provided with contact plugs 130 on the cell region and an interlayer insulation layer 120 between the contact plugs 130. A plate electrode 160 is formed over the storage electrode 140, and a dielectric film 150 is interposed between the plate electrode and the cylindrical capacitor, thus completing the cylindrical capacitor 170. An interlayer insulation layer 180 is formed over the regions of the semiconductor substrate and the cylindrical capacitor 170 in order to insulate both the plate electrode 160 of the cylindrical capacitor 170 and a subsequently formed metal wiring (not shown). A height difference t1 is generated between the cell region and the peripheral region when forming the interlayer insulation layer 180 due to the cylindrical capacitor 170.

Referring to FIG. 1B, in order to eliminate the height difference in the interlayer insulation layer 180, a photosensitive layer is coated over the insulation layer 180 and then selectively exposed and developed to form a photosensitive layer pattern M that exposes the cell region. A dry etching is performed using the photosensitive layer pattern M as an etching mask on the interlayer insulation layer 180 in the exposed cell region. The dry etching is done to a predetermined thickness.

Referring to FIG. 1C, the interlayer insulation layer 180 formed in an interface between the cell region and the peripheral region is chemical mechanical polished until the photosensitive layer pattern is removed, thereby eliminating the height difference between the cell region and the peripheral region.

As described above, in the prior art method for planarizing the insulation layer of a semiconductor device, the interlayer insulation layer in the cell region, which has the larger height, is etched using a photosensitive layer pattern as a mask. The interlayer insulation layer, which already has some of its height removed, is then chemical mechanical polished.

However, in the aforementioned prior art, the mask process and the etching process lengthen the processing time, and the production cost is increased by the cost of a photosensitive layer pattern forming process, both of which raise the unit manufacturing cost.

### BRIEF SUMMARY OF THE INVENTION

Embodiments of the present invention are directed to a method for planarizing an insulation layer, and more particularly to a method for planarizing an insulation layer of a semiconductor device which is capable of omitting a mask process and an etching process when planarizing the insulation layer.

Further, embodiments of the present invention are directed to a method for planarizing an insulation layer of a semiconductor device that decreases a unit manufacturing cost.

In one embodiment, a method for planarizing an insulation layer of a semiconductor device may comprise forming an insulation layer over a semiconductor substrate having a first region and a second region. The portion of the insulation layer in the first region is higher than the portion of the insulation layer in the second region. A metal layer is formed over the insulation layer. The metal layer is chemical mechanical polishing to expose the insulation layer portion in the first region. The exposed insulation layer portion in the first region is chemical mechanical polishing to planarize the insulation layer, and the planarized insulation layer and the remaining metal layer is chemical mechanical polishing to remove the metal layer remained in the region.

The first region is a cell region and the second region is a peripheral region.

The insulation layer may include an oxide.

The metal layer may include tungsten.

The metal layer is formed to a thickness of 200 to 3000 Å.

Chemical mechanical polishing of the metal layer is performed using a metal polishing slurry having a polishing selection ratio between the insulation layer and the metal layer of 1:10 to 1:200.

Chemical mechanical polishing of the exposed insulation layer portion is performed using an insulation layer polishing slurry having a polishing selection ratio between the metal layer and the insulation layer of 1:10 to 1:200.

Chemical mechanical polishing of the planarized insulation layer and the remaining metal layer is performed using a metal polishing slurry having a polishing selection ratio between the insulation layer and the metal layer of 1:10 to 1:200.

In another embodiment, a method for planarizing an insulation layer in a semiconductor device may comprise forming a capacitor over a cell region of a semiconductor substrate having the cell region and a peripheral region. Forming an insulation layer over a semiconductor substrate having a height difference between the cell region and the peripheral region caused by the capacitor (i.e. the cell region is higher than the peripheral region). A metal layer is then formed over the insulation layer. The metal layer is chemical mechanical polishing to expose an insulation layer portion in the cell region. The exposed insulation layer portion in the cell region is chemical mechanical polishing to planarize the insulation layer, and the planarized insulation layer and the remaining metal layer is chemical mechanical polishing to remove the metal layer remained in the peripheral region.

The insulation layer includes an oxide.

The metal layer includes tungsten.

The metal layer is formed to a thickness of 200 to 3000 Å.

The chemical mechanical polishing of the metal layer is performed using a tungsten polishing slurry having a polishing selection ratio between the insulation layer and the metal layer of 1:10 to 1:200.

The chemical mechanical polishing of the exposed insulation layer portion is performed using an insulation layer polishing slurry having a polishing selection ratio between the metal layer and the insulation layer of 1:10 to 1:200.

The chemical mechanical polishing of the planarized insulation layer and the remaining metal layer is performed using a metal polishing slurry having a polishing selection ratio between the insulation layer and the metal layer of 1:10 to 1:200.

### BRIEF DESCRIPTION OF THE DRAWINGS

FIGS. 1A to 1C are cross-sectional views illustrating steps of a prior art method for planarizing an insulation layer in a semiconductor device.

FIGS. 2A to 2E are cross-sectional views illustrating steps of a method for planarizing an insulation layer of a semiconductor device in accordance with an embodiment of the present invention.

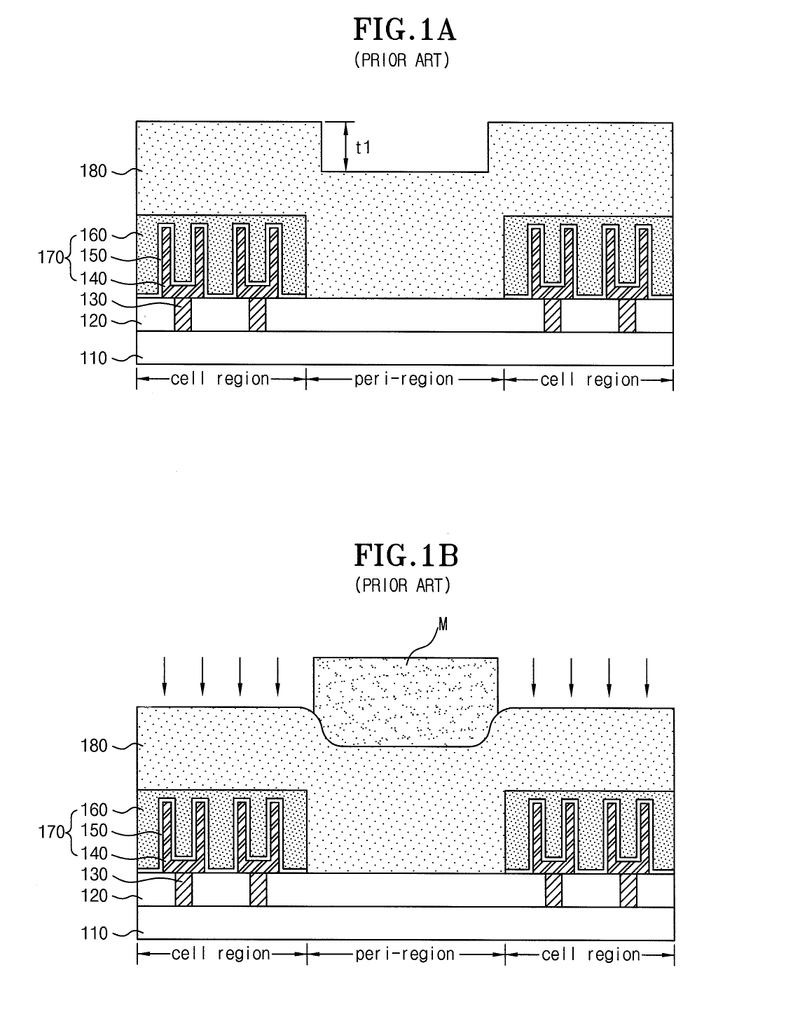

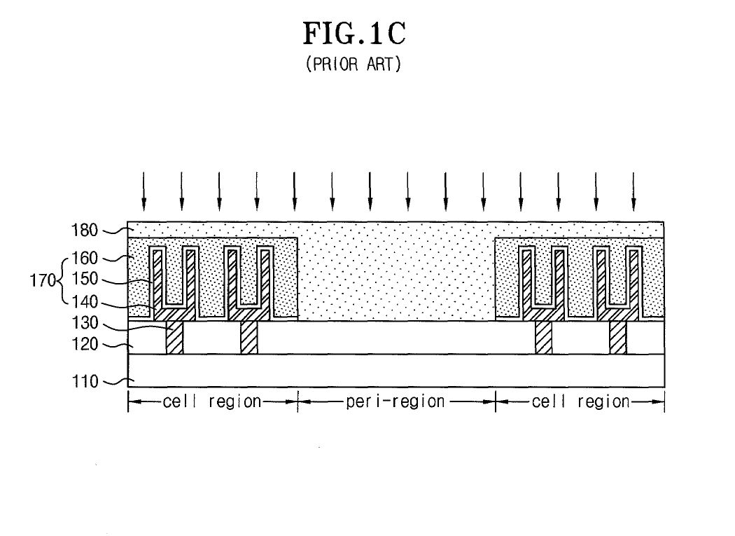

### DESCRIPTION OF SPECIFIC EMBODIMENTS

A preferred embodiment of the present invention is directed to a method for planarizing an insulation layer in a semiconductor device, in which a metal layer, such as a tungsten layer, is formed over the insulation layer, and the insulation layer is planarized by using a polishing selection ratio between the insulation layer and the tungsten layer.

In the present invention, it is not necessary to form a separate photosensitive layer pattern for planarizing the insulation layer, and it is also possible to omit a dry etching of the insulation layer. Since the planarization of the insulation layer can be accomplished using only the chemical mechanical polishing process, it is possible to simplify the manufacturing process and reduce the unit manufacturing cost. Additionally, because the dry etching process of the insulation layer can be omitted, it is possible to prevent etching defects, and thus an increase in the manufacturing yield of a device can be expected.

Hereafter, a method for planarizing an insulation layer in a semiconductor device in accordance with an embodiment of the present invention will be described with reference to the attached drawings.

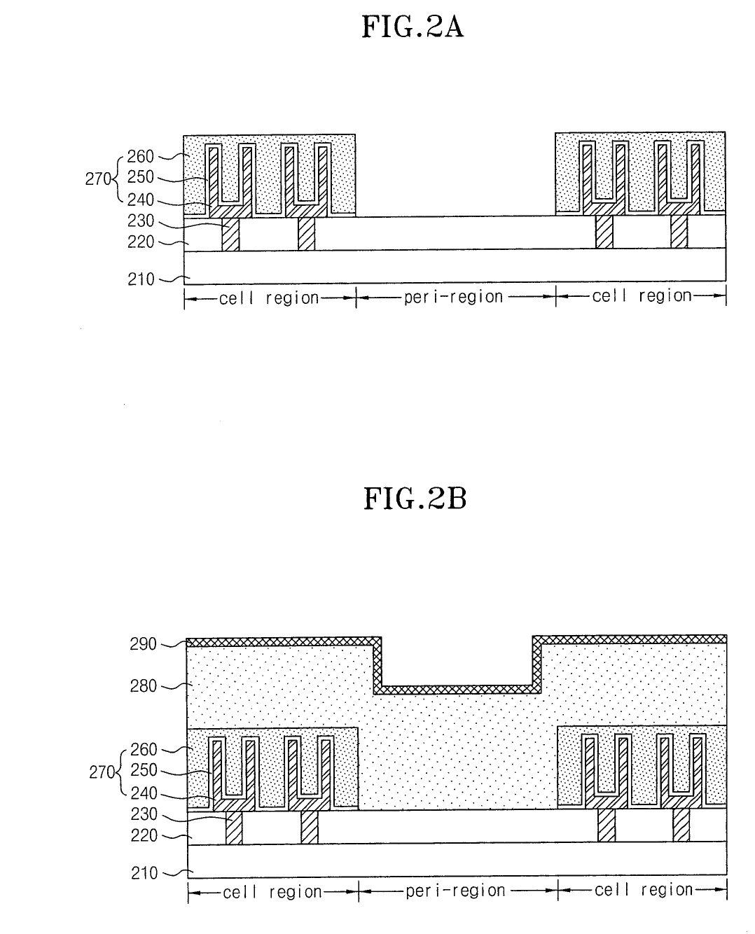

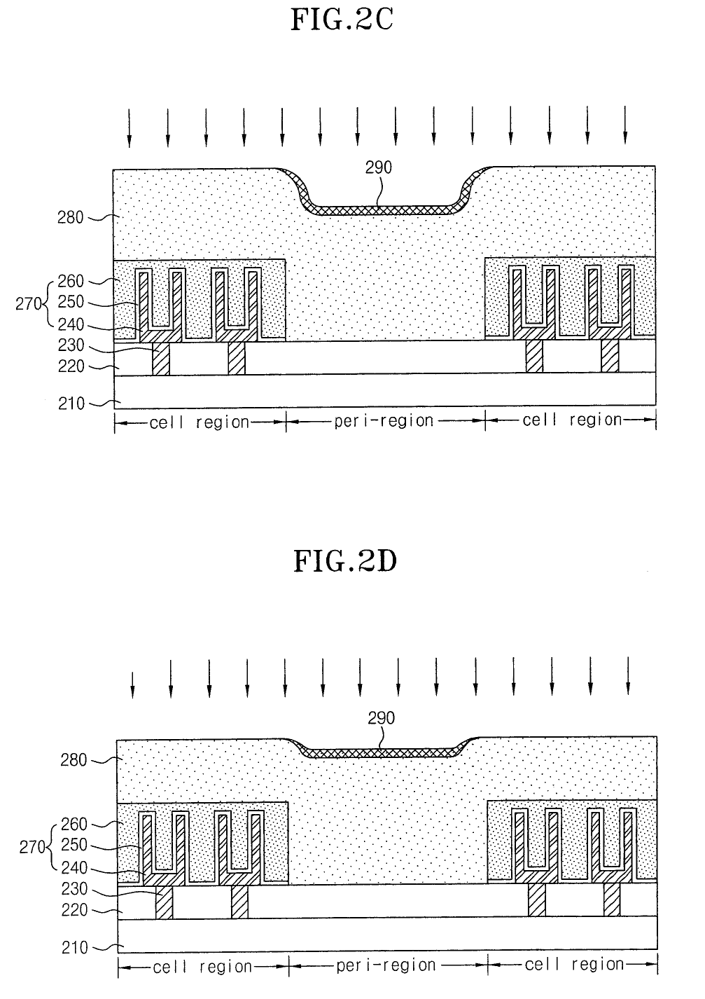

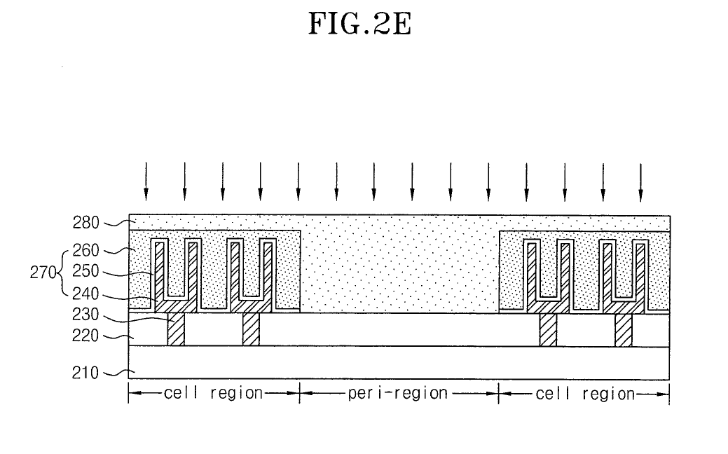

FIGS. 2A to 2E are cross-sectional views illustrating steps of a method for planarizing an insulation layer in a semiconductor device in accordance with an embodiment of the present invention.

Referring to FIG. 2A, an interlayer insulation layer 220 is formed over a semiconductor substrate 210 defined by a first region and a second region, that is, a cell region and a peripheral region. The interlayer insulation layer 220 in the cell region is etched to form a contact hole for exposing a contact plug region. A conductive layer is filled in the contact hole to form a contact plug 230. A storage electrode 240 having a cylindrical structure is formed over the interlayer insulation layer and the contact plug 230 in the cell region. A plate electrode 260 is formed over the storage electrode 240 with a dielectric film 250 interposed between the plate electrode and the storage electrode, thereby completing a cylindrical capacitor 270.

Referring to FIG. 2B, an insulation layer 280 is formed over the regions of the semiconductor substrate and the cylindrical capacitor 270 in order to insulate the plate electrode 260 of the capacitor 270 and subsequently formed metal wiring (not shown). At this time, there is a height difference t2 between the insulation layer portion formed in the cell region and the insulation portion formed in the peripheral region. This height difference is caused by the cylindrical capacitor 260. As can be seen in FIG. 2B, the height of the cell region is higher than that of the peripheral region. A metal layer 290 is deposited over the insulation layer 280 to a thickness of 200 to 3000 Å. The metal layer 290 is preferably formed of a tungsten layer.

Referring to FIG. 2C, the metal layer 290 in the cell region is chemical mechanical polished to expose the portion of the insulation layer 280 located in the cell region. This chemical mechanical polishing is performed using a tungsten polishing slurry having a polishing selection ratio between the insulation layer and the tungsten layer of 1:10 to 1:200 so that only the tungsten layer portion in the cell region having the large height is removed.

Referring to FIG. 2D, the portion of the insulation layer 280 in the cell region exposed by the first chemical mechanical polishing is then chemical mechanical polished to roughly planarize the insulation layer 280. This second chemical mechanical polishing is performed using an insulation layer polishing slurry having a polishing selection ratio between the tungsten layer and the insulation layer of 1:10 to 1:200 to roughly planarize the insulation layer 280.

At this time, the tungsten layer formed between the cell region and the peripheral region, i.e. on the stepped side wall, is easily removed by a mechanical element during the second chemical mechanical polishing and thus is of little consequence. The tungsten layer formed in the peripheral layer acts as a polishing stop layer, and thus uniformity in the substrate can be ensured.

Referring to FIG. 2E, the remained metal layer and the roughly planarized insulation layer 280 are chemical mechanical polished to remove the remaining portion of the metal layer 280 in the peripheral region. This third chemical mechanical polishing is performed using a tungsten polishing slurry having a polishing selection ratio between the insulation layer and the tungsten layer of 1:10 to 1:200 to remove the remaining tungsten layer in the peripheral region that is higher than the tungsten layer in the cell region, thereby accomplishing the planarization of the insulation layer in a semiconductor device in accordance with an embodiment of the present invention.

As is apparent from the above description, in an embodiment of the present invention, a tungsten layer is deposited over a stepped insulation layer and a chemical mechanical polishing process is performed several times using slurries having different polishing selection ratios between the insulation layer and the metal layer. An embodiment of the present invention makes it possible to planarize the insulation layer without a separate photosensitive layer forming process and dry etching process. Therefore, in an embodiment of the present invention, it is possible to accomplish a planarization of an insulation layer using only a chemical mechanical polishing. Therefore, when compared to the prior art, the number of total processes and the production cost are reduced and concerns of device defect due to dry etching are eliminated. As a result, it is possible to lower the unit manufacturing cost and increase the manufacturing yield of a device.

Although a specific embodiments of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for planarizing an insulation layer in a semiconductor device, comprising the steps of:
forming an insulation layer over a semiconductor substrate having a first region and a second region, wherein a portion of the insulation layer located in the first region is higher than a portion of the insulation layer located in the second region;
forming a metal layer over the insulation layer;
chemical mechanical polishing the metal layer to expose the insulation layer portion in the first region;
chemical mechanical polishing the exposed insulation layer portion in the first region to planarize the insulation layer; and
chemical mechanical polishing the planarized insulation layer and the remaining metal layer to remove the remaining metal layer in the second region.

2. The method for planarizing an insulation layer in a semiconductor device according to claim 1, wherein the first is a cell region and the second region is a peripheral region.

3. The method for planarizing an insulation layer in a semiconductor device according to claim 1, wherein the insulation layer includes an oxide.

4. The method for planarizing an insulation layer in a semiconductor device according to claim 1, wherein the metal layer includes tungsten.

5. The method for planarizing an insulation layer in a semiconductor device according to claim 1, wherein the metal layer is formed to a thickness of 200 to 3000 Å.

6. The method for planarizing an insulation layer in a semiconductor device according to claim 1, wherein the step of chemical mechanical polishing the metal layer to expose the insulation layer portion in the first region is performed using a metal polishing slurry having a polishing selection ratio between the insulation layer and the metal layer of 1:10 to 1:200.

7. The method for planarizing an insulation layer in a semiconductor device according to claim 1, wherein the step of chemical mechanical polishing the exposed insulation layer portion in the first region is performed using a insulation layer polishing slurry having a polishing selection ratio between the metal layer and the insulation layer of 1:10 to 1:200.

8. The method for planarizing an insulation layer in a semiconductor device according to claim 1, wherein the step of chemical mechanical polishing the planarized insulation layer and the remaining metal layer is performed using a metal polishing slurry having a polishing selection ratio between the insulation layer and the metal layer of 1:10 to 1:200.

9. A method for planarizing an insulation layer in a semiconductor device, comprising the steps of:
forming a capacitor over a cell region of a semiconductor substrate having the cell region and a peripheral region;
forming an insulation layer over the semiconductor substrate and the capacitor, wherein a portion of the insulation layer located in the cell region is higher than a portion of the insulation region located in the peripheral region due to the capacitor;
forming a metal layer over the insulation layer;
chemical mechanical polishing the metal layer to expose an insulation layer portion in the cell region;
chemical mechanical polishing the exposed insulation layer portion in the cell region to planarize the insulation layer; and
chemical mechanical polishing the planarized insulation layer and the remained metal layer to remove the metal layer remained in the peripheral region.

10. The method for planarizing an insulation layer in a semiconductor device according to claim 8, wherein the insulation layer includes an oxide.

11. The method for planarizing an insulation layer in a semiconductor device according to claim 8, wherein the metal layer includes tungsten.

12. The method for planarizing an insulation layer in a semiconductor device according to claim 8, wherein the metal layer is formed to a thickness of 200 to 3000 Å.

13. The method for planarizing an insulation layer in a semiconductor device according to claim 8, wherein the step of chemical mechanical polishing the metal layer to expose the insulation layer portion in the cell region is performed using a metal polishing slurry having a polishing selection ratio between the insulation layer and the metal layer of 1:10 to 1:200.

14. The method for planarizing an insulation layer in a semiconductor device according to claim 8, wherein the step of chemical mechanical polishing the exposed insulation layer portion in the cell region s performed using a insulation layer polishing slurry having a polishing selection ratio between the metal layer and the insulation layer of 1:10 to 1:200.

15. The method for planarizing an insulation layer in a semiconductor device according to claim 8, wherein the step of chemical mechanical polishing the planarized insulation layer and the remaining metal layer is performed using a metal polishing slurry having a polishing selection ratio between the insulation layer and the metal layer of 1:10 to 1:200.
